(19) United States
(12) Patent Application Publication
(10) Pub. No.: US 2026/0181905 A1
(43) Pub. Date: Jun. 25, 2026

(54) SEMICONDUCTOR MEMORY DEVICE

(71) Applicant: SAMSUNG ELECTRONICS CO., LTD., Suwon-si (KR)

(72) Inventors: Haeyeon Jun, Suwon-si (KR); Hyungjoon Kim, Suwon-si (KR); Jaewoo Park, Suwon-si (KR); Gukhyon Yon, Suwon-si (KR)

(73) Assignee: SAMSUNG ELECTRONICS CO., LTD., Suwon-si (KR)

(21) Appl. No.: 19/409,250

(22) Filed: Dec. 4, 2025

(30) Foreign Application Priority Data
Dec. 24, 2024 (KR) 10-2024-0196097

(51) Int. Cl. H10B 51/20; H10B 51/10; H10B 51/30; H10B 51/40; H10D 30/01; H10D 30/69

(52) U.S. Cl. CPC H10B 51/20; H10B 51/10; H10B 51/30; H10B 51/40; H10D 30/701; H10D 30/0415

(57) ABSTRACT

Provided is a semiconductor memory device including: a semiconductor substrate; a first conductive line on the semiconductor substrate and extending in a vertical direction; a channel layer above the semiconductor substrate and at least partially surrounding the first conductive line; a second conductive line above the channel layer; a ferroelectric layer between the channel layer and the second conductive line; and an insulating layer between the ferroelectric layer and the second conductive line, wherein a portion of the second conductive line overlaps the ferroelectric layer in a horizontal direction.

### CROSS-REFERENCE TO RELATED APPLICATION

This application is based on and claims priority to Korean Patent Application No. 10-2024-0196097, filed on Dec. 24, 2024, in the Korean Intellectual Property Office, the disclosure of which is incorporated by reference herein in its entirety.

### BACKGROUND

The disclosure relates to a semiconductor memory device, and more particularly, to a semiconductor memory device including a ferroelectric layer.

To satisfy requirements for superior performance and cost-effectiveness, the degree of integration of semiconductor memory devices continues to increase. Accordingly, vertical semiconductor memory devices for increasing memory capacities by stacking a plurality of memory cells in a vertical direction on a substrate have been proposed. Also, among the vertical semiconductor memory devices, a vertical semiconductor memory device that includes a ferroelectric layer as an information storage structure has been proposed. When the ferroelectric layer is contained as the information storage structure, the operating voltage may be lowered.

### SUMMARY

Provided is a semiconductor memory device that operates at a low operating voltage while achieving improved operating speed.

According to an aspect of the disclosure, a semiconductor memory device includes: a semiconductor substrate; a first conductive line on the semiconductor substrate and extending in a vertical direction; a channel layer above the semiconductor substrate and at least partially surrounding the first conductive line; a second conductive line above the channel layer; a ferroelectric layer between the channel layer and the second conductive line; and an insulating layer between the ferroelectric layer and the second conductive line, wherein a portion of the second conductive line overlaps the ferroelectric layer in a horizontal direction.

According to an aspect of the disclosure a semiconductor memory device includes: a semiconductor substrate including a memory cell region and a connection region adjacent to the memory cell region; a plurality of first conductive lines on the semiconductor substrate in the memory cell region and extending in a vertical direction; a plurality of channel layers above the semiconductor substrate and at least partially surrounding the plurality of first conductive lines; a plurality of second conductive lines respectively above the plurality of channel layers; a plurality of ferroelectric layers each between a channel layer of the plurality of channel layers and a second conductive line of the plurality of second conductive lines; an insulating layer between each of the plurality of ferroelectric layers and each of the plurality of second conductive lines; and a contact plug in the connection region, wherein the contact plug is in contact with an end of each of the plurality of second conductive lines, wherein a portion of a second conductive line among the plurality of second conductive lines overlaps a ferroelectric layer among the plurality of ferroelectric layers in a horizontal direction.

According to an aspect of the disclosure, a semiconductor memory device includes: a semiconductor substrate; a first conductive line on the semiconductor substrate and extending in a vertical direction; a channel layer above the semiconductor substrate and at least partially surrounding the first conductive line; a second conductive line above the channel layer; a ferroelectric layer between the channel layer and the second conductive line; and an insulating layer between the ferroelectric layer and the second conductive line, wherein a first portion of the second conductive line overlaps the ferroelectric layer in the vertical direction, and a second portion of the second conductive line overlaps the ferroelectric layer in a horizontal direction, and wherein the first portion of the second conductive line is closer to the first conductive line than the second portion of the second conductive line.

According to an aspect of the disclosure, a method of manufacturing a semiconductor memory device includes: alternately stacking a first channel section, a first insulating layer, a first sacrificial layer, a second sacrificial layer, and a second insulating layer on a semiconductor substrate; etching the first channel section, the first insulating layer, the first sacrificial layer, the second sacrificial layer, and the second insulating layer to form a plurality of vertical holes that expose an upper surface of the semiconductor substrate; forming a mask pattern including an opening on each of the plurality of vertical holes; forming a first channel section recess by dry-etching the first channel section using the mask pattern; filling the first channel section recess and each of the plurality of vertical holes by forming a second channel section; partially etching the second channel section to expose the plurality of vertical holes and to form a second channel section recess; filling and the plurality of vertical holes and the second channel section recess with a third channel section; etching a portion of the third channel section; at least partially removing the first sacrificial layer to form a first sacrificial layer recess; at least partially removing the second sacrificial layer to form a second sacrificial layer recess; filling the plurality of vertical holes, the first sacrificial layer recess, and the second sacrificial layer recess with a ferroelectric material; at least partially removing the ferroelectric material to form the plurality of vertical holes and a ferroelectric recess; filling the plurality of vertical holes and the ferroelectric recess with a third insulating layer; heating the ferroelectric material; removing a portion of the third insulating layer; forming a plurality of first conductive lines in each of the plurality of vertical holes; partially etching the channel layer, the first sacrificial layer, and the second sacrificial layer to form a word line cut opening; removing the first sacrificial layer and the second sacrificial layer; covering a surface of the ferroelectric layer, a surface of the first insulating layer, a surface of the second insulating layer, and a surface of the third insulating layer with a fourth insulating layer; forming a second conductive line, wherein the second conductive line is spaced apart from the ferroelectric layer with the fourth insulating layer therebetween; filling the word line cut opening; forming an upper insulating layer; and forming a contact that at least partially passes through the upper insulating layer, wherein the first wiring line is connected to the contact.

### BRIEF DESCRIPTION OF DRAWINGS

The above and other aspects and features of certain embodiments of the present disclosure will be more apparent from the following description taken in conjunction with the accompanying drawings, in which:

FIG. 1 is a plan view schematically showing components of a semiconductor memory device according to one or more embodiments;

FIG. 2A is a cross-sectional view of the semiconductor memory device of FIG. 1 taken along line A-A′;

FIG. 2B is an enlarged cross-sectional view of region CX1 of FIG. 2A;

FIG. 3A is a cross-sectional view of the semiconductor memory device of FIG. 2B taken along line Lv1 of FIG. 2B;

FIG. 3B is a cross-sectional view of the semiconductor memory device of FIG. 2B taken along line Lv2;

FIG. 3C is a cross-sectional view of the semiconductor memory device of FIG. 2B taken along line Lv3;

FIG. 4A is a cross-sectional view of a semiconductor memory device of FIG. 1 taken along a line corresponding to line A-A′;

FIG. 4B is an enlarged cross-sectional view of region CX2 of FIG. 4A;

FIGS. 5 to 18 are cross-sectional views illustrating a method of manufacturing a semiconductor memory device, according to one or more embodiments; and

FIGS. 19 to 27 are cross-sectional views illustrating a method of manufacturing a semiconductor memory device, according to one or more embodiments.

### DETAILED DESCRIPTION

Hereinafter, one or more embodiments of the disclosure are described in detail with reference to the accompanying drawings. The same reference numerals are given to the same elements in the drawings, and repeated descriptions thereof are omitted.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

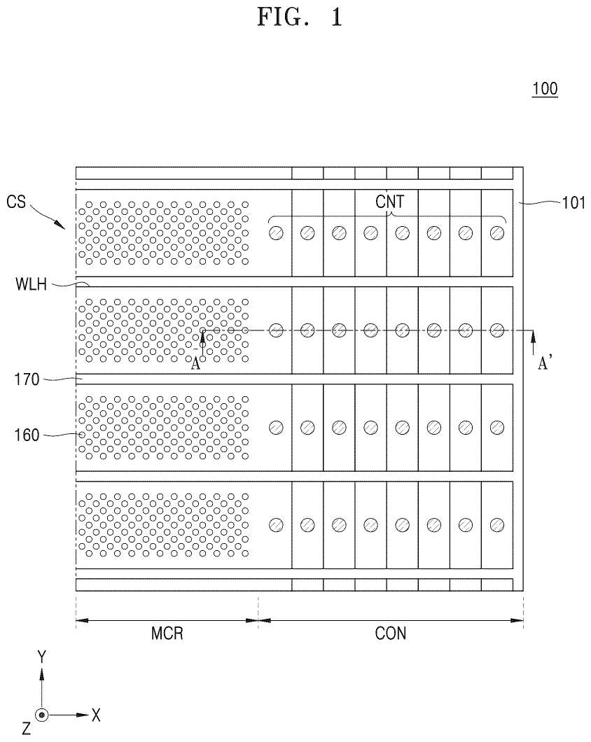

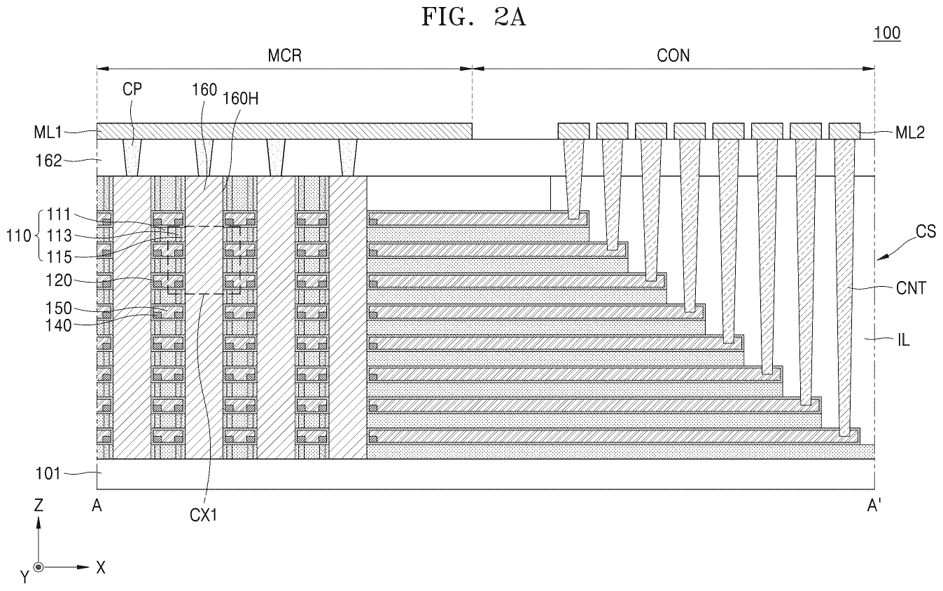

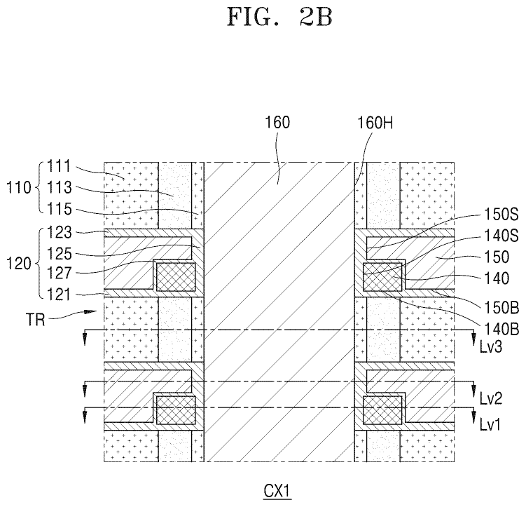

FIG. 1 is a plan view schematically showing components of a semiconductor memory device 100 according to one or more embodiments. FIG. 2A is a cross-sectional view of the semiconductor memory device 100 taken along line A-A′ of FIG. 1, and FIG. 2B is an enlarged cross-sectional view of region CX1 of FIG. 2A.

Referring to FIGS. 1, 2A, and 2B, the semiconductor memory device 100 may include a cell array structure CS including a memory cell region MCR and a connection region CON.

The memory cell region MCR may include a region in which a memory cell array is formed, and the connection region CON may include a region in which a structure for electrical connection between the memory cell array and a peripheral circuit region is formed.

A semiconductor substrate 101 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The semiconductor substrate 101 may be provided as a bulk wafer or a wafer having an epitaxial layer formed thereon. In one or more embodiments, the semiconductor substrate 101 may include a silicon on insulator (SOI) substrate or a germanium on insulator (GeOI) substrate.

In the memory cell region MCR, a plurality of channel layers 110, a plurality of ferroelectric layers 140, and a plurality of second conductive lines 150 may be alternately arranged above the semiconductor substrate 101 in a vertical direction (a Z direction). An upper insulating layer 162 may be disposed above the uppermost one of the plurality of channel layers 110.

The plurality of channel layers 110 may extend in both a first horizontal direction (an X direction) and a second horizontal direction (a Y direction). The plurality of channel layers 110 may be spaced apart from each other in the vertical direction (the Z direction).

Each of the plurality of channel layers 110 may include a first channel section 111, a second channel section 113, and a third channel section 115. The first channel section 111 may be located in the central region of each of the plurality of channel layers 110, the second channel section 113 may be disposed on both sidewalls of the first channel section 111, and the third channel section 115 may be horizontally spaced apart from the first channel section 111 with the second channel section 113 therebetween.

The first channel section 111 may form a source region of each of the plurality of channel layers 110, the third channel section 115 may form a drain region of each of the plurality of channel layers 110, and the second channel section 113 may form a channel region of each of the plurality of channel layers 110. The first channel section 111 and the third channel section 115 may include, for example, a semiconductor material doped with a dopant. For example, the first channel section 111 and the third channel section 115 may include silicon doped with a dopant. The dopant may include, for example, an n-type dopant, such as P, As, and Sb. The second channel section 113 may include, for example, a semiconductor material that is not doped with a dopant, i.e., an intrinsic semiconductor material. For example, the second channel section 113 may include silicon that is not doped with a dopant.

The plurality of ferroelectric layers 140 may be respectively disposed above the plurality of channel layers 110. Each of the plurality of ferroelectric layers 140 may be spaced apart from each of the plurality of channel layers 110 in the vertical direction (the Z direction) with a first insulating layer 121 therebetween, and may be spaced apart from a first conductive line 160 in the first horizontal direction (the X direction) with a third insulating layer 125 therebetween, which is described below. The plurality of ferroelectric layers 140 may include, for example, a ferroelectric material. The ferroelectric material may include, for example, oxide containing hafnium or zirconium. For example, the ferroelectric material may include hafnium oxide (HfO₂), hafnium zirconium oxide (Hf₁₋ₓZrₓO₂, 0≤x≤1), or a combination thereof. For example, the ferroelectric material may include hafnium oxide (HfO₂) doped with Al, C, N, Gd, Y, Ta, La, or Si, hafnium zirconium oxide (Hf₁₋ₓZrₓO₂, 0≤x≤1) doped with Al, C, N, Gd, Y, Ta, La, or Si, or a combination thereof. For example, the concentration of doped elements in the hafnium oxide (HfO₂) or the hafnium zirconium oxide (Hf₁₋ₓZrₓO₂, 0≤x≤1) that constitute the ferroelectric material may be about 0.1 at % to about 10 at %.

The ferroelectric layer 140 may exist as a solid-solution or each component material thereof may exist as a super lattice. The doped material in the ferroelectric layer 140 may exist as a dispersed structure in a thin film or exist as an aggregated structure of localized material layers in a thin film.

Each of the plurality of second conductive lines 150 may be disposed above each of the plurality of channel layers 110 and above each of the plurality of ferroelectric layers 140. Each of the plurality of second conductive lines 150 may be spaced apart from the ferroelectric layer 140 with a fourth insulating layer 127 therebetween, may be spaced apart from the channel layer 110, located below the second conductive line 150, with the first insulating layer 121 therebetween in the vertical direction (the Z direction), and may be spaced apart from the channel layers 110, located above the second conductive line 150, with a second insulating layer 123 therebetween in the vertical direction (the Z direction). Each of the plurality of second conductive lines 150 may extend in both the first horizontal direction (the X direction) and the second horizontal direction (the Y direction). Each of the plurality of second conductive lines 150 may have a T-shape on a cross-section (an X-Z cross-section) perpendicular to the second horizontal direction (the Y direction).

Each of the plurality of second conductive lines 150 may correspond to a ground selection line, a word line, and at least one string selection line. For example, the second conductive line 150 located lowermost may function as a ground selection line, the second conductive line 150 located uppermost may function as a string selection line, and the other second conductive lines 150 may function as word lines.

In one or more embodiments, inner surfaces 140S of the ferroelectric layers 140 facing each other (in cross section) with the first conductive line 160 therebetween may extend further toward the first conductive line 160 than inner surfaces 150S of the second conductive lines 150 facing each other (in cross section) with the first conductive line 160 therebetween.

In one or more embodiments, the inner surfaces 150S of the second conductive lines 150 facing each other with the first conductive line 160 therebetween may be on the same plane as the boundary surfaces between the second channel sections 113 and the third channel sections 115.

In one or more embodiments, a bottom surface 140B of the ferroelectric layer 140 included in one cell transistor TR may be at a lower vertical level than a bottom surface 150B of the second conductive line 150 included in the one cell transistor TR.

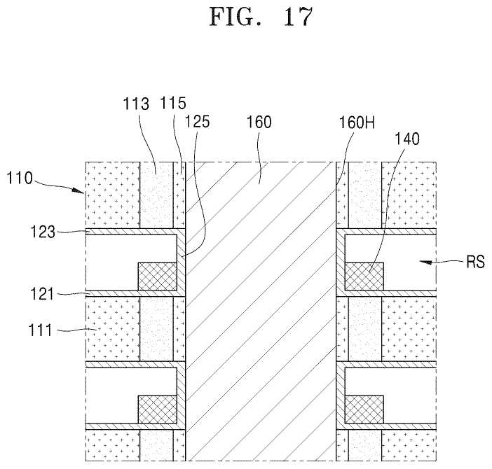

This is because, in a process of manufacturing a semiconductor memory device, which is described below, a fourth insulating layer 127 covering an exposed surface of the ferroelectric layer 140 is formed inside a recessed space RS (see FIG. 17) that provides a space in which the second conductive line 150 is formed, and then, the remainder of the recessed space RS (see FIG. 17) in which the fourth insulating layer 127 has been formed may be filled with the second conductive line 150.

In one or more embodiments, a portion of the second conductive line 150, which is relatively far from the first conductive line 160, may overlap the ferroelectric layer 140 in the horizontal directions (the X direction and the Y direction). In other words, the portion of the second conductive line 150, which is relatively far from the first conductive line 160, may be at the same vertical level as the ferroelectric layer 140 in a plan view. In addition, in one or more embodiments, another portion of the second conductive line 150, which is relatively close to the first conductive line 160, may overlap the ferroelectric layer 140 in the vertical direction (the Z direction).

The first insulating layer 121, the second insulating layer 123, the third insulating layer 125, and the fourth insulating layer 127 may be collectively defined as an insulating layer 120. FIG. 2B illustrates the first insulating layer 121, the second insulating layer 123, the third insulating layer 125, and the fourth insulating layer 127 as separate components. However, this is only for the convenience of illustration and the disclosure is not limited thereto. The boundaries between the first insulating layer 121, the second insulating layer 123, the third insulating layer 125, and the fourth insulating layer 127 may not be distinguished from each other.

The first insulating layer 121, the second insulating layer 123, the third insulating layer 125, and the fourth insulating layer 127 may each include, for example, silicon oxide, but the disclosure is not limited thereto.

One channel layer 110, one ferroelectric layer 140 disposed above the one channel layer 110, a portion of the second conductive line 150 disposed above the one channel layer 110, the fourth insulating layer 127 located between the portion of the second conductive line 150 and the one ferroelectric layer 140, and the first insulating layer 121 located between the portion of the second conductive line 150 and the one channel layer 110 and between the one ferroelectric layer 140 and the one channel layer 110 may form one cell transistor TR.

The semiconductor memory device 100 may include a plurality of cell transistors TR, and the plurality of cell transistors TR may be spaced apart from each other in the vertical direction (the Z direction). The plurality of cell transistors TR may be connected to the one first conductive line 160 that extends lengthwise in the vertical direction (the Z direction). Each of the plurality of cell transistors TR may include the first channel section 111 and the third channel section 115, i.e., a source region and a drain region, which are individually formed. In other words, the plurality of cell transistors TR may not share the source region and the drain region. Therefore, it is not necessary to apply a pass voltage and a read voltage to cells that are not selected during an operation of the semiconductor memory device 100. Accordingly, a read disturb phenomenon may be prevented when the semiconductor memory device 100 operates, and thus the operating reliability of the semiconductor memory device 100 may be improved.

The one cell transistor TR may be turned on or off electrically by a polarization phenomenon induced in the ferroelectric layer 140 due to an electric field applied to the second conductive line 150. For example, when the polarization phenomenon is induced in the ferroelectric layer 140 by the electric field applied to the second conductive line 150, carriers may be discharged from the first channel section 111, i.e., a source region, to the first conductive line 160, i.e., a bit line, via the second channel section 113 and the third channel section 115.

In one or more embodiments, the cell transistor TR of the semiconductor memory device 100 may include a single level cell (SLC) transistor. Therefore, the semiconductor memory device 100 may operate at a low operating voltage and have an improved operating speed.

Above the semiconductor substrate 101, a plurality of word line cuts 170 may extend inside a word line cut opening WLH in the first horizontal direction (the X direction). The channel layer 110 and the second conductive line 150, which are arranged between a pair of word line cuts 170, may form a single block, and the pair of word line cuts 170 may limit the width of the channel layer 110 and the second conductive line 150 in the second horizontal direction (the Y direction). The word line cuts 170 may each include an insulating structure. The word line cut 170 may have a tapered shape having a horizontal width that decreases from an upper portion to a lower portion thereof in the vertical direction (the Z direction).

Above the semiconductor substrate 101 in the memory cell region MCR, each of a plurality of first conductive lines 160 may be located inside a vertical hole 160H that passes through each of the plurality of channel layers 110 and each of the plurality of second conductive lines 150 in the vertical direction (the Z direction). Each of the plurality of first conductive lines 160 may extend inside the vertical hole 160H in the vertical direction (the Z direction). Each of the plurality of first conductive lines 160 may be in contact with the semiconductor substrate 101 on the bottom surface thereof. The plurality of first conductive lines 160 may be spaced apart from each other by a certain distance in the first horizontal direction (the X direction) and the second horizontal direction (the Y direction) on the semiconductor substrate 101. The plurality of first conductive lines 160 may be arranged in a zigzag pattern or a staggered pattern. The plurality of first conductive lines 160 may function as a bit line of semiconductor memory device 100

Each of the plurality of second conductive lines 150 and each of the plurality of first conductive lines 160 may include, for example, metal, conductive metal nitride, metal silicide, or a combination thereof. For example, each of the plurality of second conductive lines 150 and each of the plurality of first conductive lines 160 may include, but are not limited to, tungsten, nickel, cobalt, tantalum, tungsten nitride, titanium nitride, tantalum nitride, tungsten silicide, nickel silicide, cobalt silicide, tantalum silicide, or a combination thereof.

A cover insulating layer IL covering ends of the plurality of second conductive lines 150 may be located in the connection region CON. In the connection region CON, the plurality of second conductive lines 150 may extend in the first horizontal direction (the X direction) such that the lengths thereof decrease with increasing distance from the upper surface of the semiconductor substrate 101 in the vertical direction (the Z direction). That is, in the connection region CON, the plurality of second conductive lines 150 may have a stepped structure.

In the connection region CON, a contact plug CNT may be located which passes through the insulating layer 120 and is connected to the end of the second conductive line 150. The contact plug CNT may have a tapered pillar shape that decreases in width from the upper region to the lower region thereof in the vertical direction (the Z direction).

The connection region CON may include a plurality of dummy channel structures that extend in the vertical direction (the Z direction) and pass through the plurality of channel layers 110 and the plurality of second conductive lines 150. The dummy channel structures may be formed to provide structural stability during the process of manufacturing the semiconductor memory device 100.

A contact CP may pass through the upper insulating layer 162 and come into contact with the first conductive line 160, and a first wiring line ML1 in contact with the contact CP may extend in the second horizontal direction (the Y direction) on the upper insulating layer 162. In addition, a second wiring line ML2 that is in contact with the contact plug CNT on the upper insulating layer 162 may be formed in the connection region CON.

The semiconductor memory device 100 according to one or more embodiments may include the plurality of cell transistors TR, each including the one channel layer 110, the one ferroelectric layer 140 disposed above the one channel layer 110, and a portion of the second conductive line 150 disposed above the ferroelectric layer 140. Since the cell transistor TR includes the ferroelectric layer 140, the semiconductor memory device 100 may operate at a low operating voltage while ensuring excellent retention. In addition, since each of the plurality of cell transistors TR individually includes a source region and a drain region, the read disturb phenomenon may be prevented, thereby improving the operating reliability of the semiconductor memory device 100. In addition, since the cell transistor TR operates in the SLC method, the operating speed of the semiconductor memory device 100 may be improved.

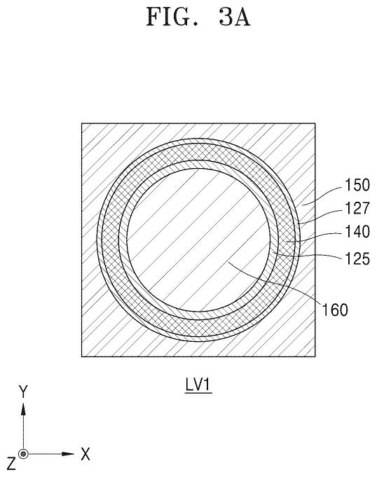

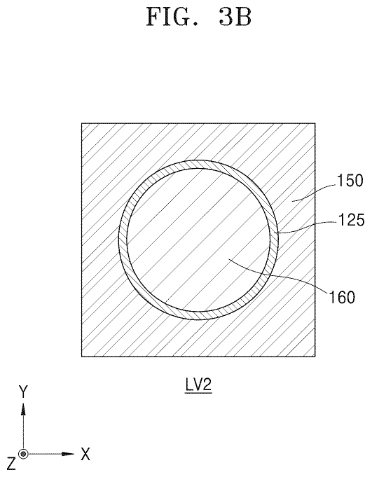

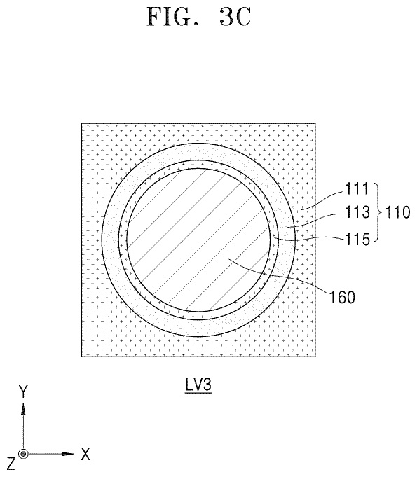

FIG. 3A is a cross-sectional view of the semiconductor memory device 100 taken along line Lv1 of FIG. 2B, FIG. 3B is a cross-sectional view of the semiconductor memory device 100 taken along line Lv2 of FIG. 2B, and FIG. 3C is a cross-sectional view of the semiconductor memory device 100 taken along line Lv3 of FIG. 2B.

Referring to FIGS. 3A and 3B, the first conductive line 160 may have a circular shape in a plan view. Also, the third insulating layer 125 surrounding the first conductive line 160, the ferroelectric layer 140 surrounding the third insulating layer 125, and the fourth insulating layer 127 surrounding the ferroelectric layer 140 may each have a ring shape surrounding the first conductive line 160.

Referring to FIG. 3C, in a plan view, the third channel section 115 surrounding the first conductive line 160 and the second channel section 113 surrounding the third channel section 115 may each have a ring shape surrounding the first conductive line 160.

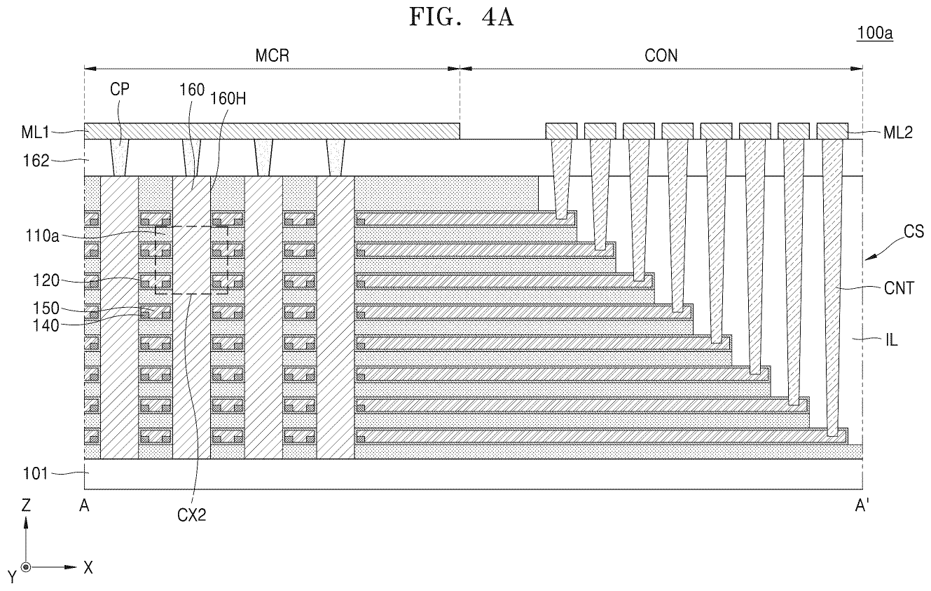

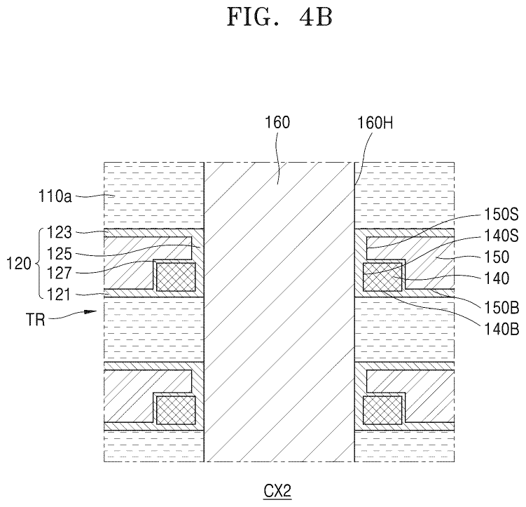

FIG. 4A is a cross-sectional view of a semiconductor memory device 100a taken along a line corresponding to line A-A′ of FIG. 1, and FIG. 4B is an enlarged cross-sectional view of region CX2 of FIG. 4A. Since components of the semiconductor memory device 100a illustrated in FIGS. 4A and 4B are similar to those of the semiconductor memory device 100 illustrated in FIGS. 1, 2A, 2B, 3A, 3B, and 3C, the description focuses on the differences therebetween.

Referring to FIGS. 4A and 4B, the semiconductor memory device 100a may be substantially identical or similar to the semiconductor memory device 100 illustrated in FIGS. 1, 2A, 2B, 3A, 3B, and 3C, except that the semiconductor memory device 100a includes a plurality of oxide semiconductor channel layers 110a.

The semiconductor memory device 100a may include the plurality of oxide semiconductor channel layers 110a disposed above the semiconductor substrate 101 in the memory cell region MCR. Each of the plurality of oxide semiconductor channel layers 110a may extend in both the first horizontal direction (the X direction) and the second horizontal direction (the Y direction). The plurality of oxide semiconductor channel layers 110a may be spaced apart from each other in the vertical direction (the Z direction) with each of the plurality of ferroelectric layers 140 and each of the plurality of second conductive lines 150 therebetween.

The plurality of oxide semiconductor channel layers 110a may include an oxide semiconductor material. The oxide semiconductor material may include, for example, indium gallium zinc oxide (IGZO) doped with dopants, such as Al and Y, In₂₋₂ₓZnₓSnₓO₃ (0<x<0.4), InₓGa₁₋ₓO (0<x<1), InTiZnO, SnO₂, or a combination thereof, but the embodiment is not limited thereto.

The plurality of oxide semiconductor channel layers 110a may not include a separate n-type dopant.

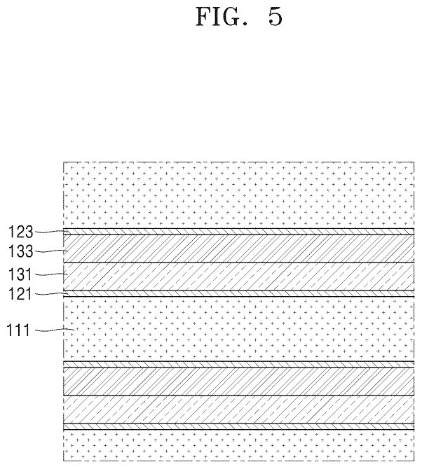

FIGS. 5 to 18 are cross-sectional views illustrating a method of manufacturing the semiconductor memory device 100, according to one or more embodiments.

Referring to FIG. 5, the first channel section 111, the first insulating layer 121, a first sacrificial layer 131, a second sacrificial layer 133, and the second insulating layer 123 may be alternately stacked on the semiconductor substrate 101 (see FIG. 2A). The process of alternately stacking the first channel section 111, the first insulating layer 121, the first sacrificial layer 131, the second sacrificial layer 133, and the second insulating layer 123 on the semiconductor substrate 101 (see FIG. 2A) may be performed repeatedly. The first sacrificial layer 131 and the second sacrificial layer 133 may provide space for forming the ferroelectric layer 140 and the second conductive line 150 in a process described below.

In one or more embodiments, the first channel section 111 may include silicon doped with an n-type dopant. In one or more embodiments, the first insulating layer 121 may include silicon oxide.

In one or more embodiments, the first sacrificial layer 131 and the second sacrificial layer 133 may each include silicon nitride.

In one or more embodiments, the silicon-nitrogen crosslink density of the silicon nitride constituting the first sacrificial layer 131 may be lower than the silicon-nitrogen crosslink density of the silicon nitride constituting the second sacrificial layer 133. Due to the difference between the silicon-nitrogen crosslink density of the silicon nitride constituting the first sacrificial layer 131 and the silicon-nitrogen crosslink density of the silicon nitride constituting the second sacrificial layer 133, the first sacrificial layer 131 may be relatively more etched by using an etchant having etch selectivity for the first sacrificial layer 131 in a process described below.

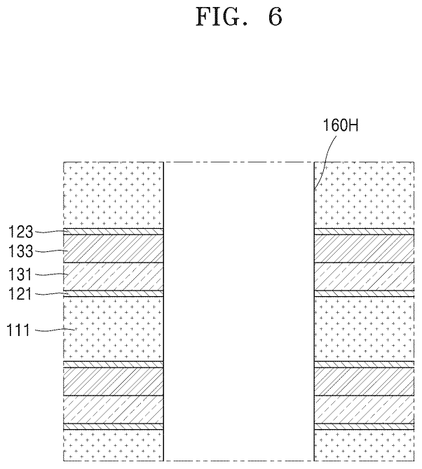

Referring to FIG. 6, the first channel section 111, the first insulating layer 121, the first sacrificial layer 131, the second sacrificial layer 133, and the second insulating layer 123 may be etched to form a plurality of vertical holes 160H that expose the upper surface of the semiconductor substrate 101 (see FIG. 2A). The plurality of vertical holes 160H may be formed, for example, by forming a mask pattern having an opening on the second insulating layer 123 located uppermost and then performing an etching process by using the mask pattern as an etching mask. The mask pattern may be removed from the second insulating layer 123 located uppermost after the plurality of vertical holes 160H are formed.

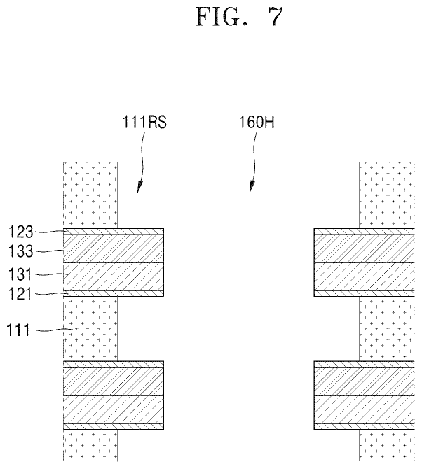

Referring to FIG. 7, the first channel section 111 exposed via each of the plurality of vertical holes 160H may be partially etched to form a first channel section recess 111RS. In one or more embodiments, a mask pattern having an opening may be formed on each of plurality of vertical holes 160H, and then, the first channel section 111 may be dry-etched by using the mask pattern as an etching mask, thereby forming the first channel section recess 111RS. In one or more embodiments, by using the etch selectivity between materials constituting the first channel section 111 and the remaining materials other than the material constituting the first channel section 111, the first channel section 111 may be partially wet-etched to form the first channel section recess 111RS.

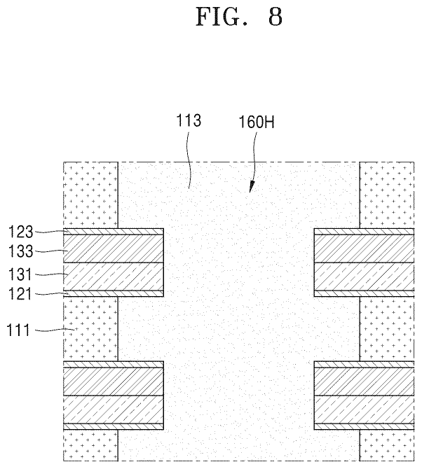

Referring to FIG. 8, the second channel section 113 may be formed, which fills the first channel section recess 111RS (see FIG. 7) and each of the plurality of vertical holes 160H. The second channel section 113 may be formed, for example, by a deposition process, such as an atomic layer deposition (ALD) process and a chemical vapor deposition (CVD) process. In one or more embodiments, the second channel section 113 may include silicon not doped with a dopant.

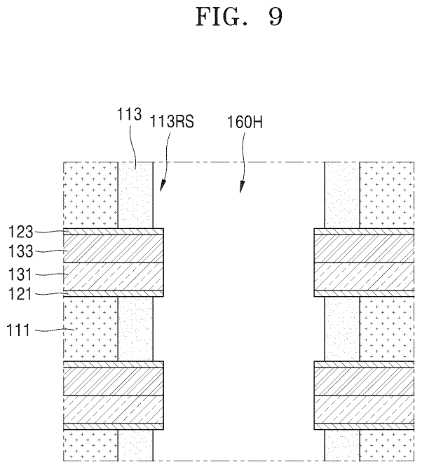

Referring to FIG. 9, the second channel section 113 may be partially etched to form the plurality of vertical holes 160H and a second channel section recess 113RS. The second channel section 113 may be partially removed, for example, by a trimming process.

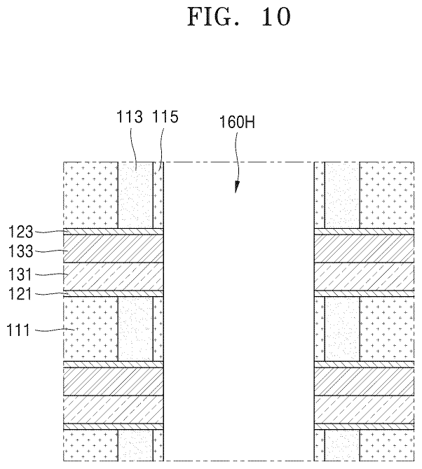

Referring to FIG. 10, the third channel section 115 may fill the second channel section recess 113RS (see FIG. 9) and the plurality of vertical holes 160H. In the third channel section 115, a portion of the third channel section 115, which fills each of the plurality of vertical holes 160H, may be etched. The third channel section 115 may be formed, for example, by a deposition process, such as an ALD process and a CVD process. The third channel section 115 may be partially removed, for example, by a trimming process. In one or more embodiments, the third channel section 115 may include silicon doped with an n-type dopant.

In one or more embodiments, after performing the process illustrated in FIG. 8 instead of performing the process illustrated in FIG. 9, the plurality of vertical holes 160H may be formed by partially etching the second channel section 113. In other words, unlike the process illustrated in FIG. 9, the second channel section 113 formed on the second channel section recess 113RS is not partially etched, and only the second channel section 113 formed on the plurality of vertical holes 160H may be partially etched. In this case, by performing a process of partially doping the second channel section 113, formed on the second channel section recess 113RS, with an n-type dopant instead of performing the process described with reference to FIG. 10, a region doped with the n-type dopant may be defined as the third channel section 115, and a region not doped with the n-type dopant may be defined as the second channel section 113.

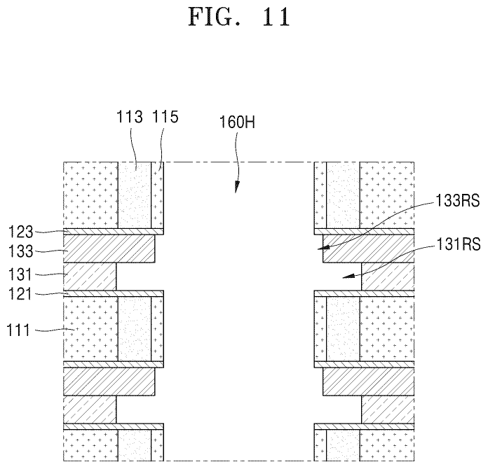

Referring to FIG. 11, the first sacrificial layer 131, exposed via each of the plurality of vertical holes 160H, may be partially removed to form a first sacrificial layer recess 131RS, and the second sacrificial layer 133, exposed via each of the plurality of vertical holes 160H, may be partially removed to form a second sacrificial layer recess 133RS. In one or more embodiments, the process of forming the first sacrificial layer recess 131RS and the second sacrificial layer recess 133RS may include a wet etching process using an etchant having etch selectivity with respect to the materials that form the first sacrificial layer 131. Since the etchant has etch selectivity with respect to the first sacrificial layer 131, the first sacrificial layer 131 may be relatively more recessed than the second sacrificial layer 133 in the process described with reference to FIG. 11.

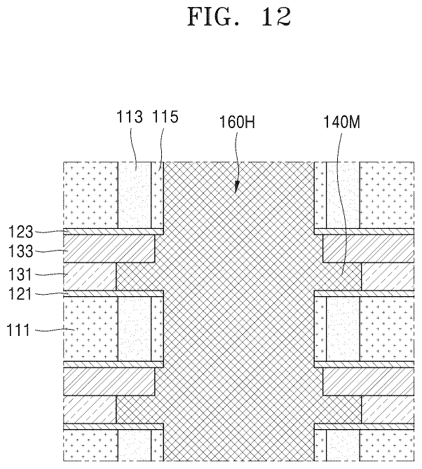

Referring to FIG. 12, a ferroelectric material 140M may fill each of the plurality of vertical holes 160H, the first sacrificial layer recess 131RS, and the second sacrificial layer recess 133RS. The ferroelectric material 140M may include, for example, hafnium oxide. The ferroelectric material 140M may be formed, for example, by a deposition process, such as an ALD process and a CVD process. The ferroelectric material 140M may be formed, for example, at a process temperature of about 500° C. or less.

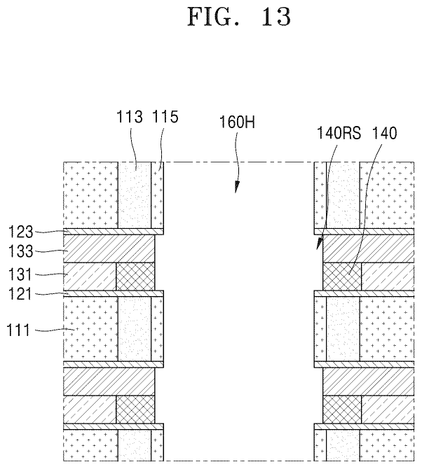

Referring to FIG. 13, the ferroelectric material 140M (see FIG. 12) may be partially removed to form the plurality of vertical holes 160H and a ferroelectric recess 140RS. The ferroelectric material 140M (see FIG. 12), which has been partially removed by the process described with reference to FIG. 13, may be defined as the ferroelectric layer 140. The ferroelectric recess 140RS may expose the surface of the second sacrificial layer 133 and the surface of the ferroelectric layer 140. The ferroelectric material 140M (see FIG. 12) may be partially removed, for example, by a trimming process.

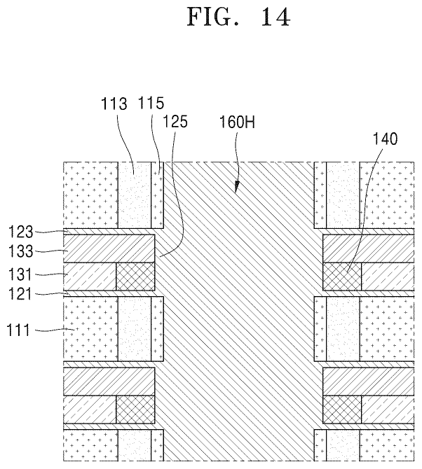

Referring to FIG. 14, a third insulating layer 125 may fill the plurality of vertical holes 160H and the ferroelectric recess 140RS (see FIG. 13). The third insulating layer 125 may include, for example, silicon oxide. The third insulating layer 125 may be formed, for example, by a deposition process.

Next, a process of crystallizing the materials that constitute the ferroelectric layer 140 may be performed. The crystallization process may include, for example, a heating process performed at a process temperature of about 200° C. to about 1100° C. The hafnium oxide constituting the ferroelectric layer 140 may be converted into o-phase due to the crystallization process, thereby exhibiting ferroelectricity.

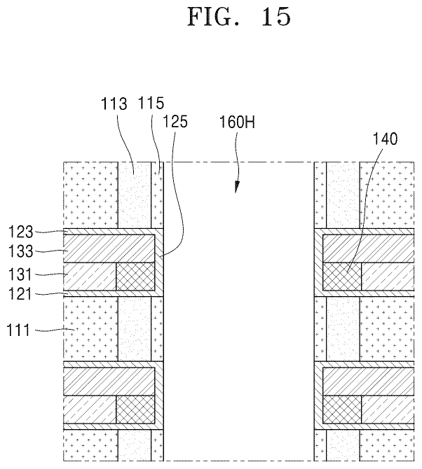

Referring to FIG. 15, with respect to the third insulating layer 125, a portion of the third insulating layer 125, which fills the plurality of vertical holes 160H, may be removed. The third insulating layer 125 may be partially removed, for example, by a trimming process. The third insulating layer 125 may be partially removed to partially expose the third channel section 115.

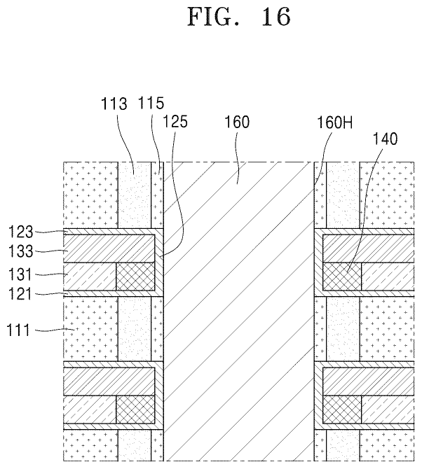

Referring to FIG. 16, the first conductive line 160 may fill each of the plurality of vertical holes 160H. The first conductive line 160 may include, for example, metal, conductive metal nitride, metal silicide, or a combination thereof. The first conductive line 160 may be formed, for example, by a deposition process.

Referring to FIG. 17, the channel layer 110, the first sacrificial layer 131, and the second sacrificial layer 133 may be partially etched to form the word line cut opening WLH (see FIG. 1), and the first sacrificial layer 131 and the second sacrificial layer 133 may be removed via the word line cut opening WLH (see FIG. 1). The first sacrificial layer 131 and the second sacrificial layer 133 may be removed, for example, by a pull-back process. As the first sacrificial layer 131 and the second sacrificial layer 133 are removed, the recessed space RS may expose the ferroelectric layer 140.

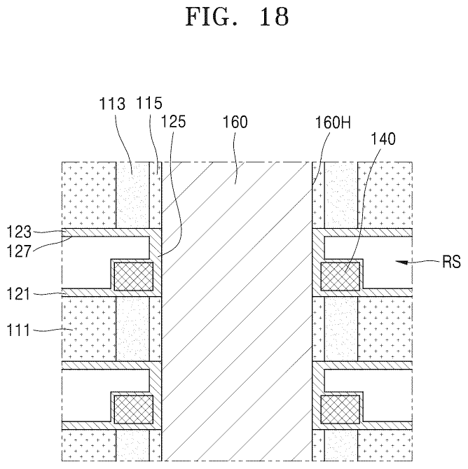

Referring to FIG. 18, the fourth insulating layer 127 may cover the surfaces of the ferroelectric layer 140, the surface of the first insulating layer 121, the surface of the second insulating layer 123, and the surface of the third insulating layer 125, which are exposed via the recessed space RS. The fourth insulating layer 127 may include, for example, silicon oxide. The fourth insulating layer 127 may be formed, for example, by a deposition process.

Next, in the resulting structure of FIG. 18, the second conductive line 150 may fill the recessed space RS (see FIG. 18). The second conductive line 150 may be spaced apart from the ferroelectric layer 140 with the fourth insulating layer 127 therebetween. The second conductive line 150 may include, for example, metal, conductive metal nitride, metal silicide, or a combination thereof. The second conductive line 150 may be formed, for example, by a deposition process.

Next, the word line cut 170 (see FIG. 1) fills the word line cut opening WLH (see FIG. 1), and the upper insulating layer 162 is formed. Subsequently, the contact CP partially passes through the upper insulating layer 162, and the first wiring line ML1 is connected to the contact CP. Accordingly, the semiconductor memory device 100 illustrated in FIGS. 1, 2A, 2B, 3A, 3B, and 3C may be manufactured.

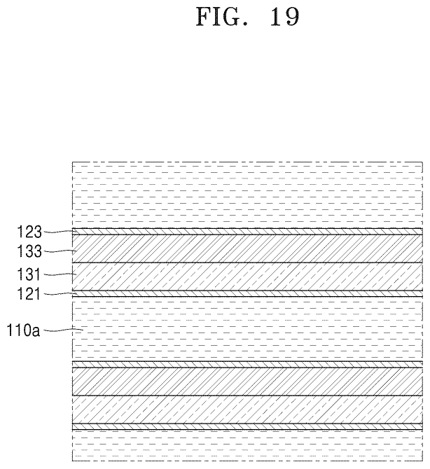

FIGS. 19 to 27 are cross-sectional views illustrating a method of manufacturing the semiconductor memory device 100a, according to one or more embodiments.

Referring to FIG. 19, the oxide semiconductor channel layer 110a, the first insulating layer 121, the first sacrificial layer 131, the second sacrificial layer 133, and the second insulating layer 123 may be alternately stacked on the semiconductor substrate 101 (see FIG. 4A). The process of alternately stacking the oxide semiconductor channel layer 110a, the first insulating layer 121, the first sacrificial layer 131, the second sacrificial layer 133, and the second insulating layer 123 on the semiconductor substrate 101 (see FIG. 4A) may be performed repeatedly. The first sacrificial layer 131 and the second sacrificial layer 133 may provide space for forming the ferroelectric layer 140 and the second conductive line 150 in a process described below.

In one or more embodiments, the oxide semiconductor channel layer 110a may include an oxide semiconductor material. The oxide semiconductor material may include, for example, IGZO doped with dopants, such as Al and Y, In₂₋₂ₓZnₓSnₓO₃ (0<x<0.4), InₓGa₁₋ₓO (0<x<1), InTiZnO, SnO₂, or a combination thereof, but the embodiment is not limited thereto. In one or more embodiments, the first insulating layer 121 may include silicon oxide.

In one or more embodiments, the first sacrificial layer 131 and the second sacrificial layer 133 may each include silicon nitride.

In one or more embodiments, the silicon-nitrogen crosslink density of the silicon nitride constituting the first sacrificial layer 131 may be lower than the silicon-nitrogen crosslink density of the silicon nitride constituting the second sacrificial layer 133.

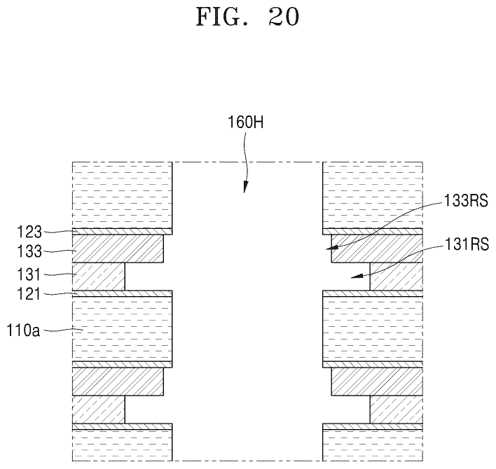

Referring to FIG. 20, the oxide semiconductor channel layer 110a, the first insulating layer 121, the first sacrificial layer 131, the second sacrificial layer 133, and the second insulating layer 123 may be etched to form the plurality of vertical holes 160H that expose the upper surface of the semiconductor substrate 101 (see FIG. 4A). Also, the first sacrificial layer recess 131RS may be formed by partially removing the first sacrificial layer 131 exposed via each of the plurality of vertical holes 160H, and the second sacrificial layer recess 133RS may be formed by partially removing the second sacrificial layer 133 exposed via each of the plurality of vertical holes 160H.

In one or more embodiments, the process of forming the first sacrificial layer recess 131RS and the second sacrificial layer recess 133RS may include a wet etching process using an etchant having etch selectivity with respect to the materials that form the first sacrificial layer 131. Since the etchant has etch selectivity with respect to the first sacrificial layer 131, the first sacrificial layer 131 may be relatively more recessed than the second sacrificial layer 133 in the process described with reference to FIG. 20.

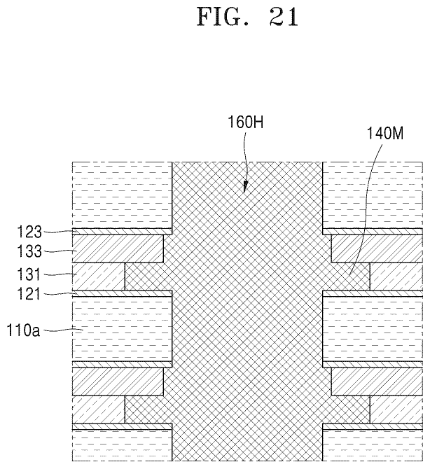

Referring to FIG. 21, a ferroelectric material 140M may fill each of the plurality of vertical holes 160H, the first sacrificial layer recess 131RS, and the second sacrificial layer recess 133RS. The ferroelectric material 140M may include, for example, hafnium oxide. The ferroelectric material 140M may be formed, for example, by a deposition process, such as an ALD process and a CVD process. The ferroelectric material 140M may be formed, for example, at a process temperature of about 500° C. or less.

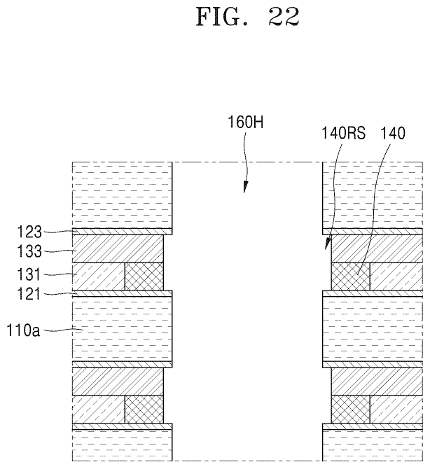

Referring to FIG. 22, the ferroelectric material 140M (see FIG. 21) may be partially removed to form the plurality of vertical holes 160H and a ferroelectric recess 140RS. The ferroelectric material 140M (see FIG. 21), which has been partially removed by the process described with reference to FIG. 21, may be defined as the ferroelectric layer 140. The ferroelectric recess 140RS may expose the surface of the second sacrificial layer 133 and the surface of the ferroelectric layer 140. The ferroelectric material 140M (see FIG. 21) may be partially removed, for example, by a trimming process.

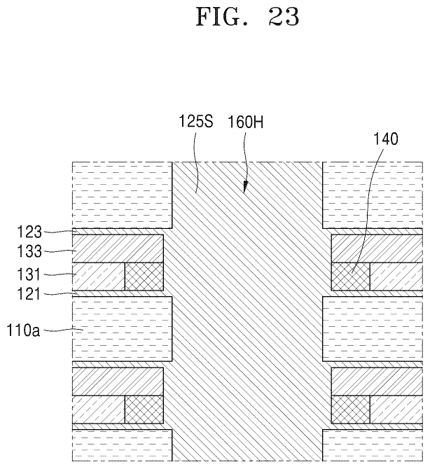

Referring to FIG. 23, a third insulating material layer 125S may fill the plurality of vertical holes 160H and the ferroelectric recess 140RS (see FIG. 22). The third insulating material layer 125S may include, for example, silicon oxide. The third insulating material layer 125S may be formed, for example, by a deposition process.

Next, a process of crystallizing the materials that constitute the ferroelectric layer 140 may be performed. The crystallization process may include, for example, a heating process performed at a process temperature of about 200° C. to about 1100° C. The hafnium oxide constituting the ferroelectric layer 140 may be converted into o-phase due to the crystallization process, thereby exhibiting ferroelectricity.

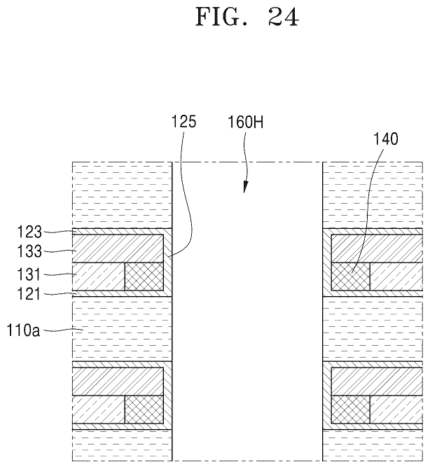

Referring to FIG. 24, with respect to the third insulating material layer 125S (see FIG. 23), a portion of the third insulating material layer 125S (see FIG. 23), which fills the plurality of vertical holes 160H, may be removed to form the third insulating layer 125. The third insulating material layer 125S (see FIG. 23) may be partially removed, for example, by a trimming process. The third insulating material layer 125S (see FIG. 23) may be partially removed to partially expose the third channel section 115.

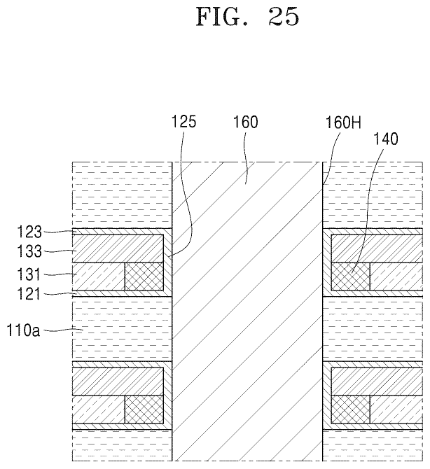

Referring to FIG. 25, the first conductive line 160 may fill each of the plurality of vertical holes 160H. The first conductive line 160 may include, for example, metal, conductive metal nitride, metal silicide, or a combination thereof. The first conductive line 160 may be formed, for example, by a deposition process.

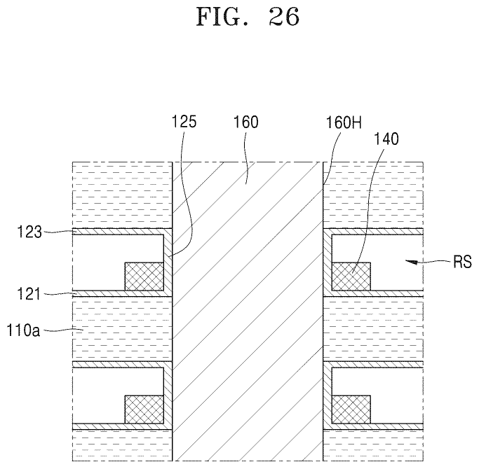

Referring to FIG. 26, the oxide semiconductor channel layer 110a, the first sacrificial layer 131, and the second sacrificial layer 133 may be partially etched to form the word line cut opening WLH (see FIG. 1), and the first sacrificial layer 131 and the second sacrificial layer 133 may be removed via the word line cut opening WLH (see FIG. 1). The first sacrificial layer 131 and the second sacrificial layer 133 may be removed, for example, by a pull-back process. As the first sacrificial layer 131 and the second sacrificial layer 133 are removed, the recessed space RS may expose the ferroelectric layer 140. For example, the etchant used in the pull-back process may include phosphoric acid.

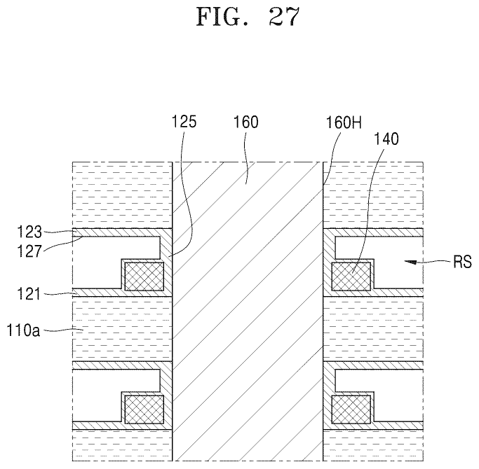

Referring to FIG. 27, the fourth insulating layer 127 may cover the surfaces of the ferroelectric layer 140, the surface of the first insulating layer 121, the surface of the second insulating layer 123, and the surface of the third insulating layer 125, which are exposed via the recessed space RS. The fourth insulating layer 127 may include, for example, silicon oxide. The fourth insulating layer 127 may be formed, for example, by a deposition process.

Next, in the resulting structure of FIG. 27, the second conductive line 150 may fill the recessed space RS (see FIG. 27). The second conductive line 150 may be spaced apart from the ferroelectric layer 140 with the fourth insulating layer 127 therebetween. The second conductive line 150 may include, for example, metal, conductive metal nitride, metal silicide, or a combination thereof. The second conductive line 150 may be formed, for example, by a deposition process.

Next, the word line cut 170 (see FIG. 1) fills the word line cut opening WLH (see FIG. 1), and the upper insulating layer 162 is formed. Subsequently, the contact CP partially passes through the upper insulating layer 162, and the first wiring line ML1 is connected to the contact CP. Accordingly, the semiconductor memory device 100a illustrated in FIGS. 4A and 4B may be manufactured.

While the disclosure has been particularly shown and described with reference to one or more embodiments thereof, it will be understood that various changes in form and details may be made therein without departing from the spirit and scope of the following claims.

What is claimed is:

1. A semiconductor memory device comprising:
a semiconductor substrate;
a first conductive line on the semiconductor substrate and extending in a vertical direction;
a channel layer above the semiconductor substrate and at least partially surrounding the first conductive line;
a second conductive line above the channel layer;
a ferroelectric layer between the channel layer and the second conductive line; and
an insulating layer between the ferroelectric layer and the second conductive line,
wherein a portion of the second conductive line overlaps the ferroelectric layer in a horizontal direction.

2. The semiconductor memory device of claim 1,
wherein the channel layer comprises: a first channel section; a third channel section; and a second channel section between the first channel section and the third channel section,
wherein the third channel section is closer to the first conductive line than the first channel section, and
wherein the third channel section at least partially surrounds the first conductive line, the second channel section at least partially surrounds the third channel section, and the first channel section at least partially surrounds the second channel section.

3. The semiconductor memory device of claim 2, wherein the first channel section and the third channel section each comprise a semiconductor material doped with a dopant, and
wherein the second channel section comprises an intrinsic semiconductor material.

4. The semiconductor memory device of claim 2, wherein a boundary surface between the second channel section and the third channel section is on a same plane as an inner surface of the second conductive line.

5. The semiconductor memory device of claim 1, wherein the channel layer comprises an oxide semiconductor material.

6. The semiconductor memory device of claim 1, wherein the ferroelectric layer is spaced apart from the second conductive line.

7. The semiconductor memory device of claim 1, wherein an inner surface of the ferroelectric layer is closer to the first conductive line than an inner surface of the second conductive line.

8. The semiconductor memory device of claim 1, wherein a bottom surface of the ferroelectric layer is at a lower vertical level than a bottom surface of the second conductive line.

9. The semiconductor memory device of claim 1, wherein a portion of the second conductive line, adjacent to the first conductive line, overlaps the ferroelectric layer in the vertical direction.

10. The semiconductor memory device of claim 1, wherein the channel layer and the second conductive line extend in the horizontal direction.

11. A semiconductor memory device comprising:
a semiconductor substrate comprising a memory cell region and a connection region adjacent to the memory cell region;
a plurality of first conductive lines on the semiconductor substrate in the memory cell region and extending in a vertical direction;
a plurality of channel layers above the semiconductor substrate and at least partially surrounding the plurality of first conductive lines;
a plurality of second conductive lines respectively above the plurality of channel layers;
a plurality of ferroelectric layers each between a channel layer of the plurality of channel layers and a second conductive line of the plurality of second conductive lines;
an insulating layer between each of the plurality of ferroelectric layers and each of the plurality of second conductive lines; and
a contact plug in the connection region, wherein the contact plug is in contact with an end of each of the plurality of second conductive lines,
wherein a portion of a second conductive line among the plurality of second conductive lines overlaps a ferroelectric layer among the plurality of ferroelectric layers in a horizontal direction.

12. The semiconductor memory device of claim 11, wherein the plurality of channel layers and the plurality of second conductive lines each have a stepped configuration in the connection region.

13. The semiconductor memory device of claim 11, wherein one of the plurality of channel layers, a second conductive line above the one of the plurality of channel layers among the plurality of second conductive lines, and a ferroelectric layer between the one of the plurality of channel layers and the second conductive line above the one of the plurality of channel layers, among the plurality of ferroelectric layers, constitute a single level cell transistor.

14. The semiconductor memory device of claim 11, wherein a channel layer among the plurality of channel layers comprises a first channel section, a third channel section, and a second channel section located between the first channel section and the third channel section,
wherein the third channel section is closer to a given first conductive line among the plurality of first conductive lines than the first channel section,
wherein the third channel section at least partially surrounds the given first conductive line, the second channel section at least partially surrounds the third channel section, and the first channel section at least partially surrounds the second channel section, and
wherein the first channel section and the third channel section each comprise a semiconductor material doped with a dopant, and the second channel section comprises an intrinsic semiconductor material.

15. The semiconductor memory device of claim 11, wherein a channel layer among the plurality of channel layers comprises an oxide semiconductor material.

16. The semiconductor memory device of claim 11, wherein an inner surface of a ferroelectric layer among the plurality of ferroelectric layers is closer to a given first conductive line among the plurality of first conductive lines than an inner surface of a corresponding second conductive line among the plurality of second conductive lines, and
wherein a bottom surface of the ferroelectric layer is at a lower vertical level than a bottom surface of the corresponding second conductive line.

17. The semiconductor memory device of claim 11, wherein a ferroelectric layer among the plurality of ferroelectric layers is spaced apart from a corresponding second conductive line among the plurality of second conductive lines.

18. The semiconductor memory device of claim 11, wherein the insulating layer comprises silicon oxide.

19. A semiconductor memory device comprising:
a semiconductor substrate;
a first conductive line on the semiconductor substrate and extending in a vertical direction;
a channel layer above the semiconductor substrate and at least partially surrounding the first conductive line;
a second conductive line above the channel layer;
a ferroelectric layer between the channel layer and the second conductive line; and
an insulating layer between the ferroelectric layer and the second conductive line,
wherein a first portion of the second conductive line overlaps the ferroelectric layer in the vertical direction, and a second portion of the second conductive line overlaps the ferroelectric layer in a horizontal direction, and
wherein the first portion of the second conductive line is closer to the first conductive line than the second portion of the second conductive line.

20. The semiconductor memory device of claim 19, wherein the ferroelectric layer is spaced apart from the second conductive line.
